(19) United States
(12) Patent Application Publication
(10) Pub. No.: US 2010/0096752 A1
(43) Pub. Date: Apr. 22, 2010

(54) SEMICONDUCTOR DEVICE

(76) Inventor: Masaji RI, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/560,579

(22) Filed: Sep. 16, 2009

(30) Foreign Application Priority Data
Oct. 21, 2008 (JP) 2008-271229

(51) Int. Cl. H01L 23/498

(52) U.S. Cl. 257/738; 257/E23.069

(57) ABSTRACT

A semiconductor device according to an aspect of the present invention comprises a package board having first and second surfaces, first external terminals on the first surface which are arranged in matrix, and second external terminals on the first surface which are arranged apart from the first external terminals. Each of the second external terminals includes first and second through holes which extend from the first surface to the second surface, and a metal layer on the first surface which is provided between the first and second through holes. The metal layer passes through the first and second through holes to the second surface.

### CROSS-REFERENCE TO RELATED APPLICATIONS

This application is based upon and claims the benefit of priority from prior Japanese Patent Application No. 2008-271229, filed Oct. 21, 2008, the entire contents of which are incorporated herein by reference.

### BACKGROUND OF THE INVENTION

1. Field of the Invention

The present invention relates to an interposer such as BGA (Ball Grid Array) and LGA (Land Grid Array).

2. Description of the Related Art

An interposer such as BGA or LGA is used, for example, when chips having different functions are contained in a package to constitute an SIP (System in Package) (for example, see Jpn. Pat. Appln. KOKAI Publication Nos. 2003-141485 and 2003-264260).

The interposer is required to have a constant reliability to stress generated by, for example, bending and impact; however, it is difficult to secure the reliability. Specifically, constant stress determined in a reliability test causes generation of such a failure mode that an external terminal (for example, a solder ball) is peeled from a package board.

However, as a matter of fact, no sufficient measures have been taken against the failure mode, due to limitations such as cost and standard (for example, see, JEDEC STANDARD, Embedded Multi Media Card (eMMC) Product Standard, Standard Capacity, JESD84-A41, June 2007, JEDEC SOLID STATE TECHNOLOGY ASSOCIATION).

Namely, in terms of cost, a package board with intensity may not be used, and in terms of standards, since adherence between the package board and a metal layer depends on the manufacturing method, it is hardly improved.

### BRIEF SUMMARY OF THE INVENTION

A semiconductor device according to an aspect of the present invention comprises a package board having first and second surfaces, first external terminals on the first surface which are arranged in matrix, and second external terminals on the first surface which are arranged apart from the first external terminals. Each of the second external terminals includes first and second through holes which extend from the first surface to the second surface, and a metal layer on the first surface which is provided between the first and second through holes. The metal layer passes through the first and second through holes to the second surface.

### BRIEF DESCRIPTION OF THE SEVERAL VIEWS OF THE DRAWING

FIG. 1 is a cross-sectional view of a semiconductor device according to an embodiment of the invention;

FIG. 2 is a plan view showing a layout of solder balls;

FIG. 3 is a plan view showing a layout of external terminals as an embodiment;

FIGS. 4 to 7 are cross-sectional views, each along line X-X in FIG. 3;

FIG. 8 is a plan view showing a layout of the external terminals as a comparative example;

FIG. 9 is a cross-sectional view along line Y-Y in FIG. 8;

FIG. 10 is a view showing a result of a bend test;

FIGS. 11 to 13 are plan views, each showing a variation;

FIG. 14 is a plan view showing a positional relationship of two through holes;

FIG. 15 is a view showing an eMMC architecture; and

FIG. 16 is a view showing a layout of eMMC external terminals.

### DETAILED DESCRIPTION OF THE INVENTION

A semiconductor device of an aspect of the present invention will be described below in detail with reference to the accompanying drawings.

### 1. Outline

A semiconductor device according to an embodiment of the invention is applied to an interposer such as BGA or LGA in which external terminals are arranged in a matrix on one side of a package board. In this interposer, the size of the package board and the positions of the external terminals are determined by a standard (for example, a JEDEC standard).

For example, an eMMC (embedded Multi Media Card) includes first external terminals arranged in a matrix on one side of the package board and second external terminals arranged on one side of the package board to be apart from the first external terminals.

In the embodiment of the invention, in the above interposer, in order to realize no peeling of the first and second external terminals from the package board, an anchor structure is adopted in the second external terminals.

As the anchor structure, each of metal layers as the external terminals arranged on one side of the package board is drawn to the other side of the package board through at least two through holes provided in the package board, and the external terminals are fixed to the package board.

Specifically, each of the second external terminals is constituted of first and second through holes penetrating from one side of the package board to the other side and a metal layer provided between the first and second through holes on one side of the package board. The end portion of the metal layer passes through the first and second through holes to reach the other side of the package board.

According to the anchor structure, even when the package board is formed of a brittle material such as a halogen-free base material, for instance, a solder ball is not peeled from the package board along with a portion of the package board by virtue of an anchor effect. Further, even in poor adherence between the package board and the metal layer, for instance, the solder ball is not peeled from the package board along with the metal layer by virtue of the anchor effect.

Thus, an interposer structure in which the external terminal is hardly peeled from the package board can be realized.

### 2. Embodiment

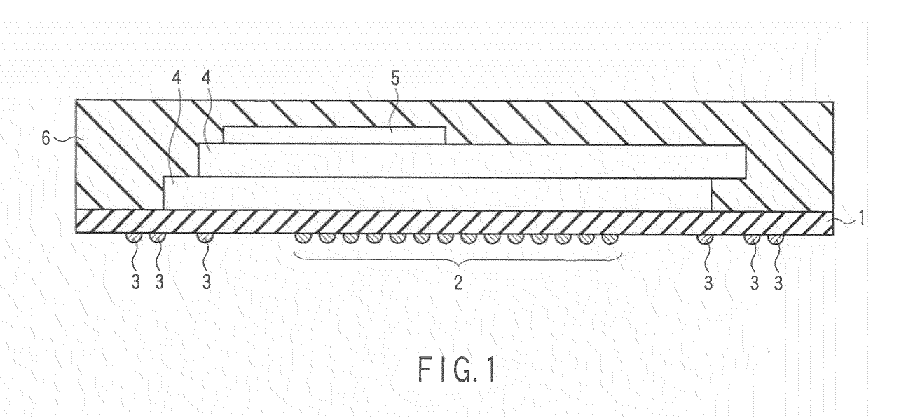

FIG. 1 is a cross-sectional view of a semiconductor device according to an embodiment of the invention.

The semiconductor device is, for example, an eMMC, and the size of the package board and the positions of the external terminals are based on a standard (for example, JEDEC standard).

Package board 1 is, for example, a glass epoxy board, and a halogen-free base material. Package board 1 may be a single layer or include layers.

Package board 1 has on its one side first solder balls 2 arranged in a matrix and second solder balls 3 arranged apart from first solder balls 2.

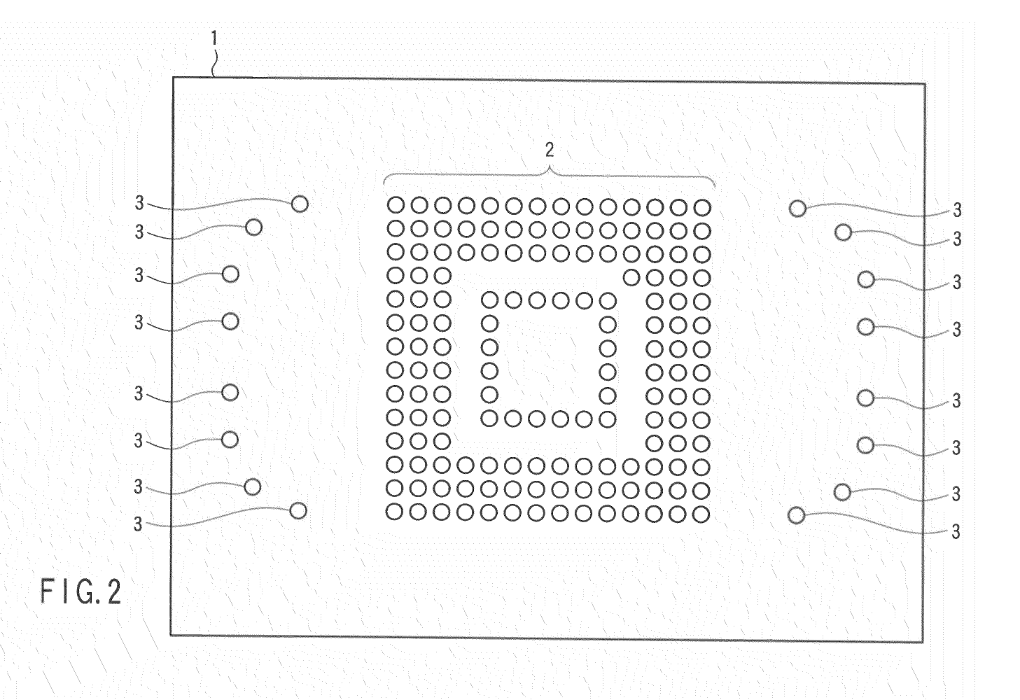

The specific layouts of first solder balls 2 and second solder balls 3 are shown in FIG. 2.

Package board 1 further has semiconductor chips arranged on the other side of Package board 1. In this embodiment, two memory chips (for example, flash memory chips) 4 are mounted on package board 1, and controller chip 5 is mounted on two memory chips 4.

A power supply chip may be further mounted on controller chip 5.

Memory chips 4 and controller chip 5 on the other side of package board 1 are covered by resin layer 6.

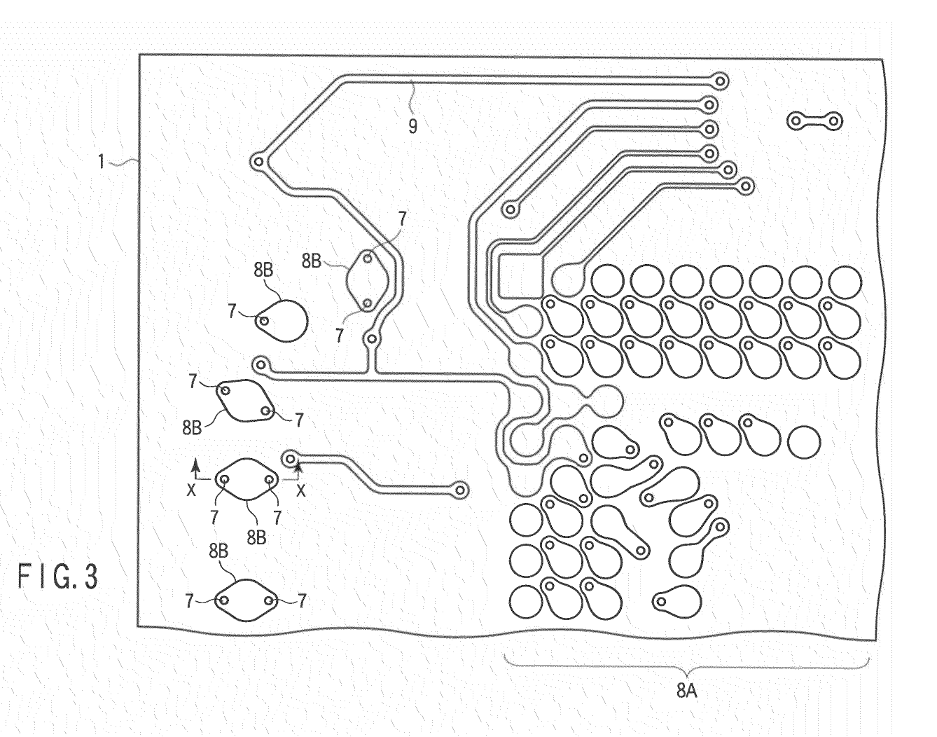

FIG. 3 shows a configuration of external terminals of the semiconductor device of FIG. 1.

Package board 1 has on its one side first external terminals 8A arranged in a matrix and second external terminals 8B arranged apart from first external terminals 8A.

Each of first and second external terminals 8A and 8B is constituted of a metal layer (for example, a copper foil). Metal wiring (for example, copper wiring) 9 extends from first and second external terminals 8A and 8B.

At least two of second external terminals 8B are constituted of first and second through holes 7 penetrating from one side of package board 1 to the other side and a metal layer provided between the first and second through holes on one side of package board 1. The end portion of the metal layer passes through first and second through holes 7 to reach the other side of package board 1.

A portion of or all of second external terminals 8B may be valid terminals actually used as interfaces or an invalid terminal which are not actually used as the interfaces.

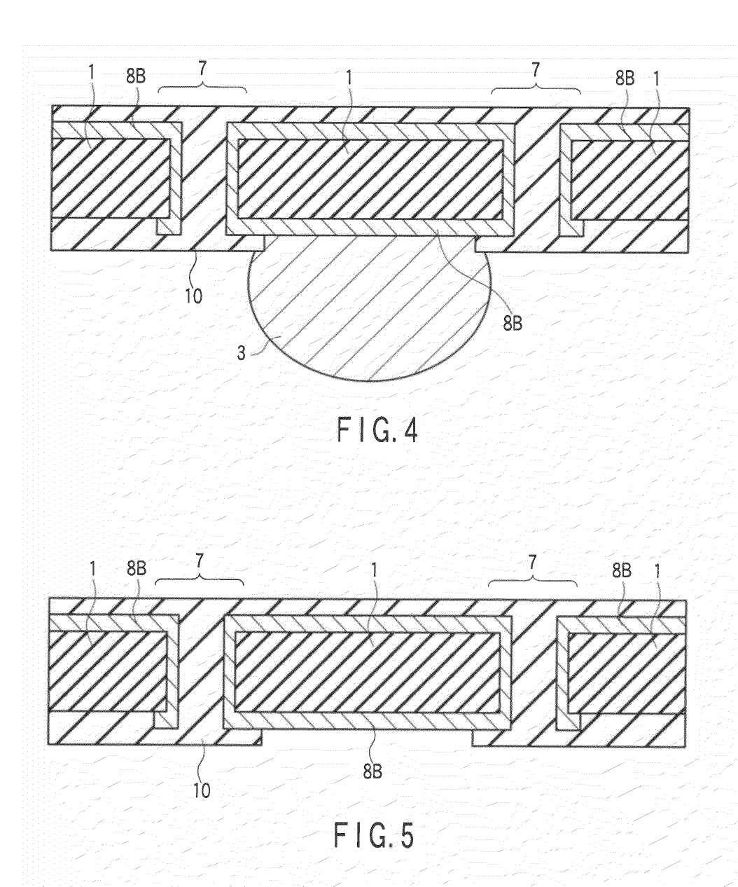

FIG. 4 is a cross-sectional view along line X-X in FIG. 3.

However, FIG. 4 further illustrates a solder ball 3 and a resin layer 10, which are not illustrated in FIG. 3.

The configuration of this embodiment is characterized in that second external terminal (metal layer) 8B has the anchor structure. Namely, first and second through holes 7 are provided in package board 1, and the end portions of second external terminal 8B between the first and second through holes on one side of package board 1 pass through first and second through holes 7 to reach the other side of package board 1.

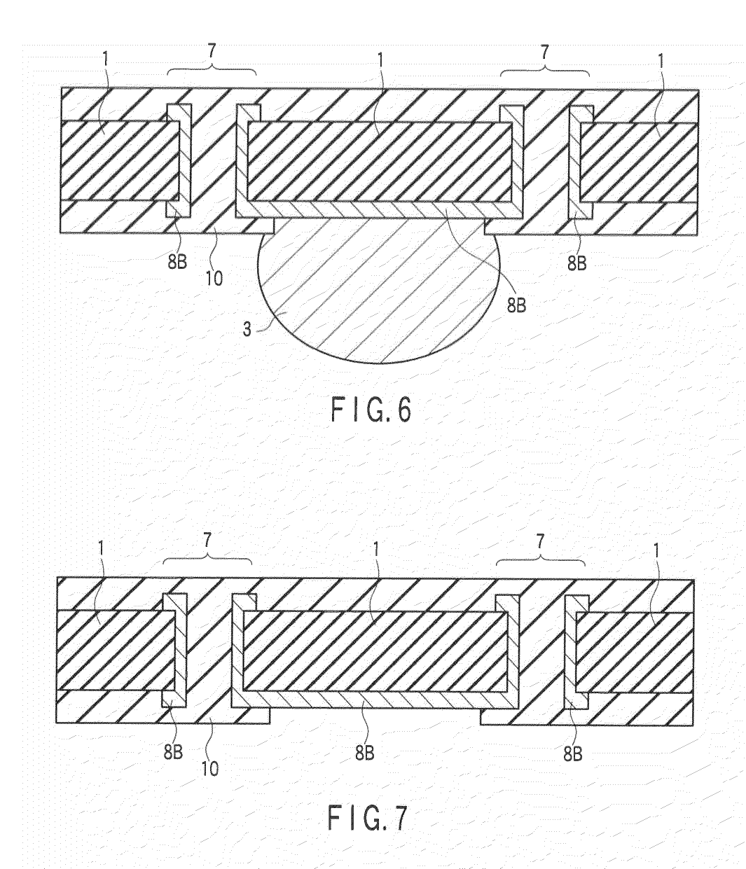

The end portions of second external terminal 8B pass through first and second through holes 7 to be connected to each other on the other side of package board 1 (including a case in which a part of the end portion is connected and another part thereof is not connected). However, as shown in FIG. 6, the end portions of second external terminal 8B may not be connected to each other on the other side of package board 1.

Resin layer 10 covers the both sides of package board 1 and fills first and second through holes 7. Resin layer 10 has an opening between first and second through holes 7 on one side of package board 1.

Resin layer 10 is formed of, for example, a solder resist.

Solder ball 3 is combined with second external terminal 8B exposed from the opening of resin layer 10. As shown in FIGS. 5 and 7, the solder ball may not be provided.

As described above, according to the interposer structure according to the embodiment of the invention, the anchor effect is imparted to the external terminal (metal layer), whereby the adherence between the external terminal and the package board can be enhanced, and a constant reliability can be secured against stress generated by, for example, bending and impact.

### 3. Bend Test Result

The anchor effect of the semiconductor device according to the embodiment of the invention is described.

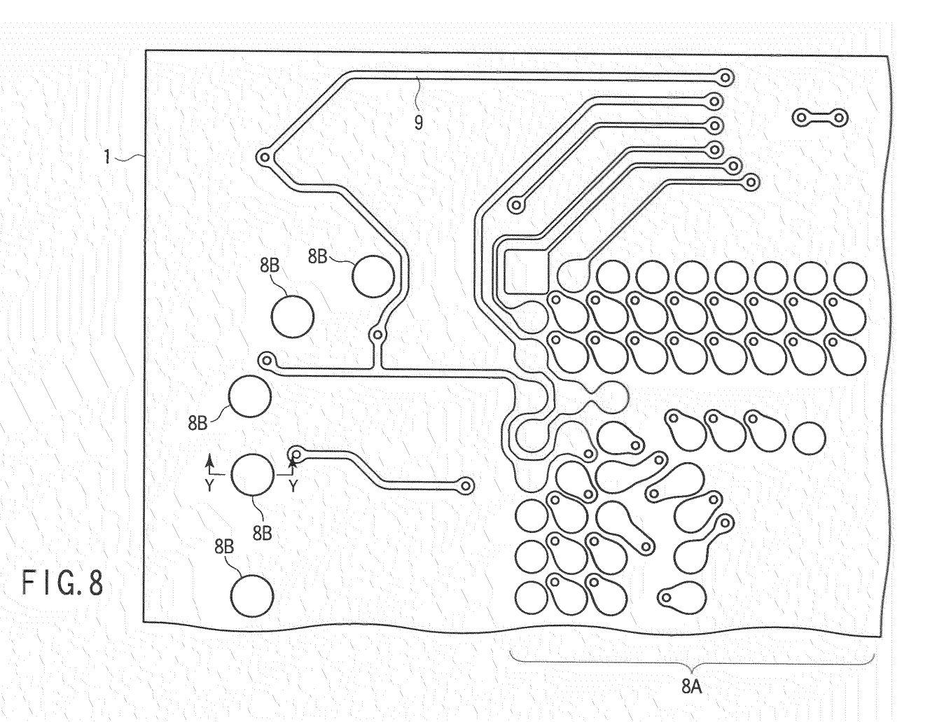

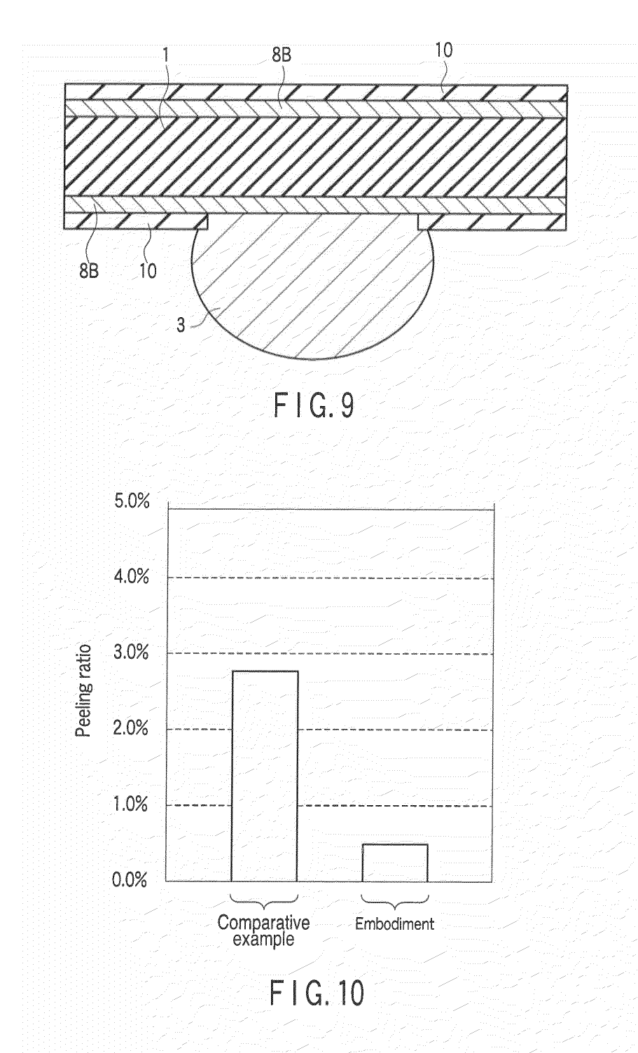

In this embodiment, the interposer having the configuration shown in FIGS. 3 and 4 is used. As a comparative example, an interposer having a configuration shown in FIGS. 8 and 9 is used.

FIG. 9 is a cross-sectional view along line Y-Y in FIG. 8. FIG. 9 further illustrates solder ball 3 and resin layer 10 which are not illustrated in FIG. 8.

In the embodiment and the comparative example, the layouts of first and second external terminals 8A and 8B and the layout of metal wiring 9 are the same as each other. The embodiment and the comparative example are different only in the configuration of second external terminals 8B.

Namely, in the embodiment, 80% or more of the second external terminals 8B have the anchor structure having two through holes 7, and, in the comparative example, all second external terminals 8B are constituted of only a metal layer without providing any through hole.

In FIG. 9, reference numerals 1, 3, 8B, and 10 respectively denote the package board, the solder ball, the second external terminal (metal layer), and the resin layer.

The anchor effect is confirmed by a bend test.

In the bend test, for instance, a specimen (the embodiment/the comparative example) is firmly fixed to a test board through the solder ball, and in this state, the rate, at which the solder ball is peeled from a test board when a constant impact is applied to the test board, is examined.

FIG. 10 shows the result of the bend test.

1000 or more specimens are examined in the embodiment and the comparative example.

In the embodiment, the peeling of the solder ball does not occur in most specimens, and the rate of peeling of the solder ball (average value) is as small as 0.5%. Meanwhile, in the comparative example, the peeling of the solder ball occurs in most specimens, and the rate of peeling of the solder ball (average value) is as large as 2.8%.

Thus, the anchor effect of the semiconductor device according to the embodiment of the invention is effective.

### 4. Variation

The anchor effect is generated by relating at least two through holes to one external terminal. Further, it is important to provide at least two through holes in different directions with respect to one external terminal.

Namely, although one through hole may be provided in a conventional external terminal, in this case, the anchor effect that would be expected in the invention cannot be obtained. This is apparent from the above bend test result.

In view of the above, the variation of the semiconductor device according to the embodiment of the invention is described.

A configuration shown in FIG. 11 relates to the embodiment which serves as a basis for the variation. Namely, external terminal (metal layer) 8B is provided between two through holes 7.

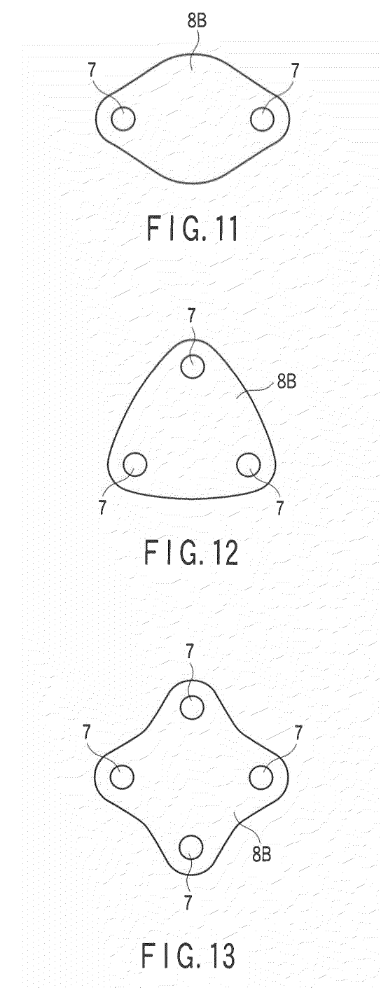

A configuration shown in FIG. 12 has a characteristic in that external terminal (metal layer) 8B is provided between three through holes 7 separated from each other by a constant distance. In this configuration, when two of three through holes 7 are selected, the external terminal 8B can be interpreted to be provided between the two through holes.

A configuration shown in FIG. 13 has a characteristic in that four through holes 7 are arranged so that lines connecting them form a cross shape or a square shape, and external terminal (metal layer) 8B is provided between four through holes 7.

It is considered that the anchor effect is large in order of FIG. 11 <FIG. 12 <FIG. 13, and, at the same time, the number of through holes increases. Thus, which of those configurations is used is determined in consideration of the anchor effect and the layout on the package board.

Next, the variation of the direction of the through hole is described.

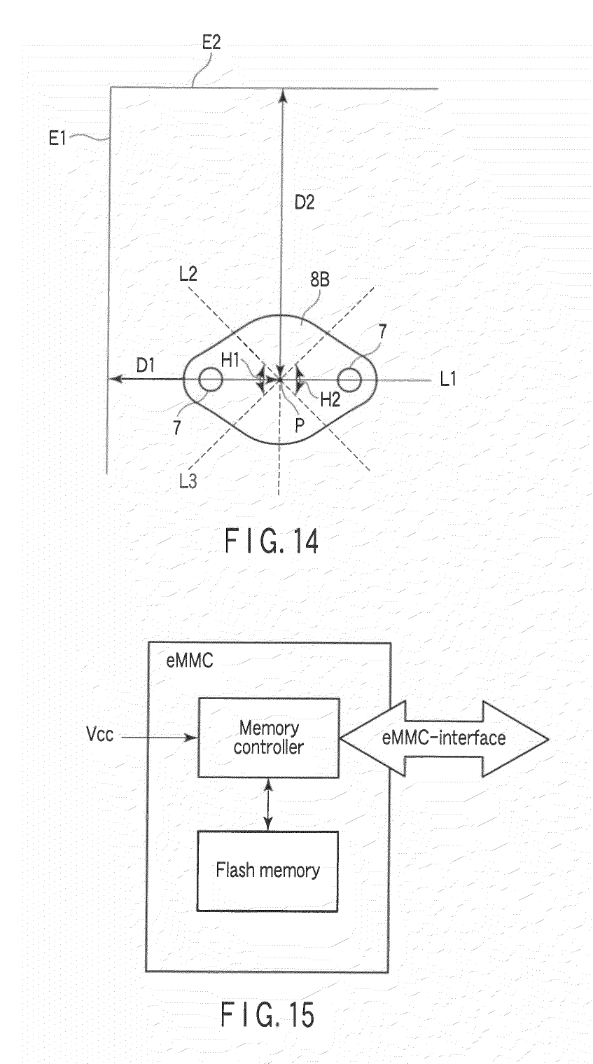

FIG. 14 shows the direction of the through hole for obtaining the maximum anchor effect when the two through holes are made correspond to one external terminal.

One of the two through holes is disposed on the side of side E1 of the package board closest to center point O of external terminal (metal layer) 8B between the through holes, and the other one is disposed on the opposite side of side E1 of the package board.

Namely, distance D1 from center point O of external terminal 8B to side E1 of the package board is smaller than distance D2 from center point O of external terminal 8B to side E2 of the package board. In this case, one of the two through holes is disposed on the side of side E1 of the package board, and the other one is disposed on the opposite side of side E1 of the package board.

Here, side E1 of the package board means range H1 from line L2 to line L3 on the side of side E1, lines L2 and L3 being respectively drawn from side to side at an angle of 45 degrees with respect to line L1 which is vertical to side E1 of the package board.

Meanwhile, the opposite side of side E1 of the package board means range H2 from line L2 to line L3 on the opposite side of side E1, lines L2 and L3 being respectively drawn from side to side at an angle of 45 degrees with respect to line L1 which is vertical to side E1 of the package board.

### 5. Application Example

An example in which the invention is applied to the eMMC is described.

FIG. 15 shows an eMMC architecture.

The eMMC is constituted of a flash memory and a memory controller. Power supply potential Vcc is applied to the memory controller, and data is input and output through an eMMC interface.

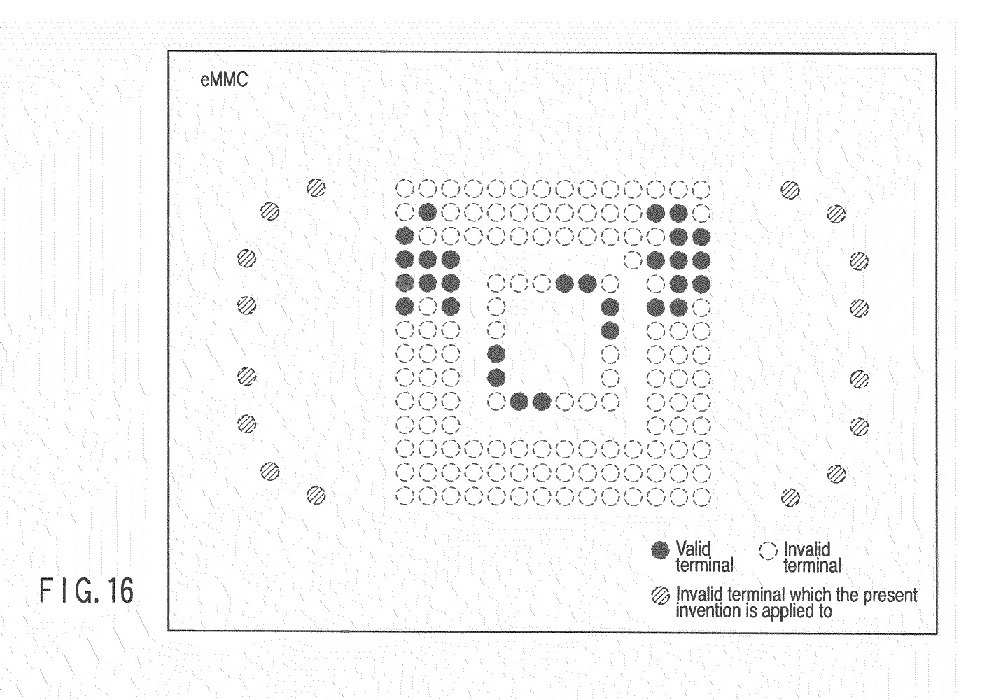

FIG. 16 shows a layout of eMMC external terminals.

First external terminals arranged in a matrix are constituted of valid terminals and invalid terminals. All of second external terminals arranged apart from the first external terminals are the invalid terminals.

When all the second external terminals are not used, there is such an effect that the configuration of the invention is easily applied thereto.

The invention is effective when the package board is formed of a base material free from a halogenated flame retardant (for example, a halogen-free base material) or a base material with a small content of a halogenated flame retardant. Further, the invention has a great effect when the package board is formed of a base material containing a flame retardant such as an antimony-based flame retardant, a phosphorous flame retardant, a metal hydroxide-based flame retardant, borate, zinc stannate, and Zr compound. Furthermore, the invention is effective when the package board is formed of a basis material with a large content of an antimony oxide, a basis material containing, for example, ester phosphate, a basis material containing, for example, aluminum hydroxide, magnesium hydroxide, and calcium hydroxide, and a basis material containing, for example, borate, zinc stannate, and a Zr compound.

### 6. Conclusion

According to the invention, the interposer structure in which the external terminal is hardly peeled from the package board can be realized.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a package board having first and second surfaces;
first external terminals on the first surface; and
second external terminals on the first surface which are arranged apart from the first external terminals,
wherein the second external terminals include first and second through holes which extend from the first surface to the second surface, and a metal layer on the first surface which is provided between the first and second through holes,
wherein the metal layer passes through the first and second through holes to the second surface.

2. The device according to claim 1,
wherein the first through hole is nearer to a side of the package board than the second through hole, and the side is the nearest side to a middle of the first and second through holes.

3. The device according to claim 1,
wherein the metal layer on the second surface is provided between the first and second through holes.

4. The device according to claim 1,
further comprising a resin layer which covers the metal layer on the first and second surfaces and fills the first and second through holes.

5. The device according to claim 1,
wherein the resin layer has an opening on the first surface between the first and second through holes.

6. The device according to claim 1,
wherein the package board is made from a halogen-free base material.

7. The device according to claim 1,
wherein the package board is a glass epoxy board.

8. The device according to claim 1,
wherein the first external terminals are provided at a center area of the package board.

9. The device according to claim 1,
wherein the second external terminals are provided at a edge area of the package board.

10. The device according to claim 1,
wherein the first external terminals are provided between the second external terminals.

11. The device according to claim 1,
wherein each of the first external terminals is one of a valid terminal and an invalid terminal.

12. The device according to claim 1, further comprising
solder balls on the first and second external terminals.

13. The device according to claim 1, further comprising
chips which are stacked on the second surface of the package board.

14. The device according to claim 13,
wherein the chips are electrically connected to the first and second external terminals.

15. The device according to claim 13,
wherein the chips includes a memory chip and a controller chip which controls the memory chip.

16. The device according to claim 15,
wherein the controller chip is stacked on the memory chip.

17. The device according to claim 15,
wherein the memory chip is a flash memory.

18. The device according to claim 1,
wherein each of the second external terminals includes a third through hole which extends from the first surface to the second surface, the metal layer is provided between the first, second and third through holes, and the metal layer passes through the third through hole to the second surface.

19. The device according to claim 1,
wherein each of the second external terminals includes third and fourth through holes which extend from the first surface to the second surface, the metal layer is provided between the first, second, third and fourth through holes, and the metal layer passes through the third and fourth through holes to the second surface.

20. The device according to claim 1,
wherein the device is an embedded multi media card.
